(19) United States
(12) Patent Application Publication
(10) Pub. No.: US 2011/0207281 A1
(43) Pub. Date: Aug. 25, 2011

(54) SEMICONDUCTOR DEVICE AND METHOD OF PRODUCING SEMICONDUCTOR DEVICE

(76) Inventor: Junichi KAMOSHITA, Miyagi (JP)

(21) Appl. No.: 13/023,775

(22) Filed: Feb. 9, 2011

(30) Foreign Application Priority Data
Feb. 22, 2010 (JP) 2010-035901

(51) Int. Cl. H01L 21/336

(52) U.S. Cl. 438/291; 257/E21.424

(57) ABSTRACT

A method of producing a semiconductor device includes the steps of forming a trench in a semiconductor substrate of a first conductive type so that an active region having a first portion and a second region is formed; implanting a first impurity of the first conductive type at an implantation angle between 30 degrees and 45 degrees relative to a normal line in an implantation direction rotating relative to the normal line so that a first channel diffusion region and a channel stopper region of the first conductive type are formed; filling the trench with an insulation layer; implanting a second impurity of a second conductive type so that a second channel diffusion region of the second conductive type is formed; forming a gate insulation film on the first portion and the second portion; and forming a gate electrode on the gate insulation film.

### BACKGROUND OF THE INVENTION AND RELATED ART STATEMENT

The present invention relates to a semiconductor device and a method of producing the semiconductor device. More specifically, the present invention relates to a semiconductor device including a semiconductor integrated circuit, in which a field effect transistor (FET) of an enhancement type and a field effect transistor (FET) of a depletion type are formed, and a method of producing the semiconductor device.

A field effect transistor (FET) has been widely used as a transistor of a semiconductor integrated circuit such as a decoder circuit of a semiconductor storage unit such as an ROM (Read Only Memory). Such a semiconductor integrated circuit is mainly configured such that a field effect transistor (FET) of an enhancement type and a field effect transistor (FET) of a depletion type are integrated (refer to Patent Reference).

Patent Reference: Japanese Patent Publication No. 11-174405

FIGS. 1(A) and 1(B) are schematic plan views showing a conventional method of producing a semiconductor device including a semiconductor integrated circuit, in which a field effect transistor (FET) of the enhancement type and a field effect transistor (FET) of the depletion type are formed.

As shown in FIG. 1(A), a trench is formed in a P-type silicon (Si) substrate to form an active region 11 with a specific width. Then, a P-type impurity is implanted into the active region 11 to form a channel diffusion region of the enhancement type. In the next step, after the trench is filled with an insulation layer 12, a resist film is formed through a photolithography technology for covering an area except regions 13. Then, an N-type impurity is implanted into the regions 13 using the resist film as a mask, thereby forming channel diffusion regions of the depletion type.

In the next step, as shown in FIG. 1(B), after the mask is removed and a gate oxide film (not shown) is formed, gate electrodes 14 are formed. Accordingly, effect transistors 15 (FET) of the enhancement type and effect transistors 16 (FET) of the depletion type are formed.

In the conventional method of producing the semiconductor device described above, the channel diffusion region of the enhancement type is formed in an entire area of the active region 11. Accordingly, in order to implant the N-type impurity for forming the channel diffusion region of the depletion type in the later step, it is necessary to use the mask. As a result, it is necessary to perform the additional step of forming the mask, thereby increasing a manufacturing cost.

Further, in the conventional method of producing the semiconductor device, it is necessary to provide a margin for matching the mask through the photolithography technology. Accordingly, it is difficult to reduce a size of the semiconductor device.

In view of the problems described above, an object of the present invention is to provide a semiconductor device and a method of producing the semiconductor device capable of solving the problems of the conventional method. In the present invention, it is possible to reduce a size of the semiconductor device and a manufacturing cost of the semiconductor device.

Further objects and advantages of the invention will be apparent from the following description of the invention.

### SUMMARY OF THE INVENTION

In order to attain the objects described above, according to an aspect of the present invention, a method of producing a semiconductor device includes the steps of: forming a trench in a main surface of a semiconductor substrate of a first conductive type so that an active region having a first portion with a first width and a second region with a second width greater than the first width is formed in the semiconductor substrate; implanting a first impurity of the first conductive type in the semiconductor substrate at an implantation angle between 30 degrees and 45 degrees relative to a normal line of the main surface in an implantation direction rotating relative to the normal line so that a channel diffusion region of the first conductive type is formed in the first portion and a channel stopper region of the first conductive type is formed in the second portion; filling the trench with an insulation layer; implanting a second impurity of a second conductive type different from the first conductive type in the semiconductor substrate so that a channel diffusion region of the second conductive type is formed between the channel stopper regions in the second portion; forming a gate insulation film on the first portion and the second portion; and forming a gate electrode on the gate insulation film.

As described above, in the aspect of the present invention, the method of producing the semiconductor device includes the steps of: the steps of: forming the trench in the main surface of the semiconductor substrate of the first conductive type so that the active region having the first portion with the first width and the second region with the second width greater than the first width is formed in the semiconductor substrate; implanting the first impurity of the first conductive type in the semiconductor substrate at the implantation angle between 30 degrees and 45 degrees relative to the normal line of the main surface in the implantation direction rotating relative to the normal line so that the channel diffusion region of the first conductive type is formed in the first portion and the channel stopper region of the first conductive type is formed in the second portion; filling the trench with the insulation layer; implanting the second impurity of the second conductive type different from the first conductive type in the semiconductor substrate so that the channel diffusion region of the second conductive type is formed between the channel stopper regions in the second portion; forming the gate insulation film on the first portion and the second portion; and forming the gate electrode on the gate insulation film.

As described above, in the present invention, it is possible to reduce a size of the semiconductor device and a manufacturing cost thereof.

### BRIEF DESCRIPTION OF THE DRAWINGS

FIGS. 1(A) and 1(B) are schematic plan views showing a conventional method of producing a semiconductor device including a semiconductor integrated circuit;

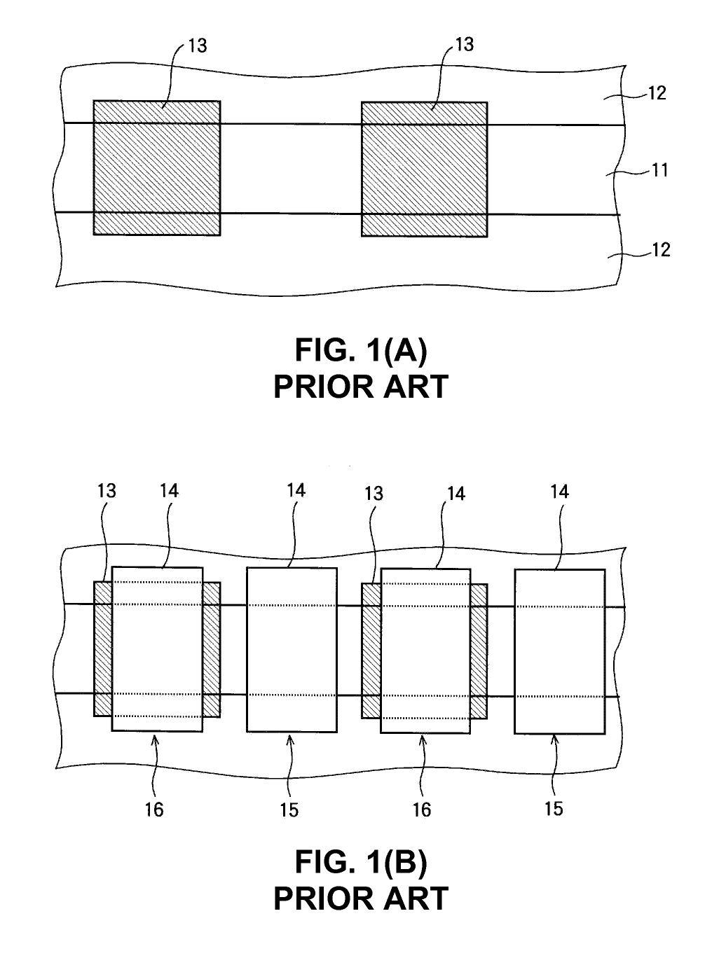

FIGS. 2(A) to 2(C) are schematic views No. 1 showing a method of producing a semiconductor device according to an embodiment of the present invention, wherein FIG. 2(A) is a schematic plan view thereof, FIG. 2(B) is a schematic sectional view thereof taken along a line 2B-2B in FIG. 2(A), and FIG. 2(C) is a schematic sectional view thereof taken along a line 2C-2C in FIG. 2(A);

FIGS. 3(A) to 3(C) are schematic views No. 2 showing the method of producing the semiconductor device according to the embodiment of the present invention, wherein FIG. 3(A) is a schematic plan view thereof, FIG. 3(B) is a schematic sectional view thereof taken along a line 3B-3B in FIG. 3(A), and FIG. 3(C) is a schematic sectional view thereof taken along a line 3C-3C in FIG. 3(A);

FIGS. 4(A) to 4(C) are schematic views No. 3 showing the method of producing the semiconductor device according to the embodiment of the present invention, wherein FIG. 4(A) is a schematic plan view thereof, FIG. 4(B) is a schematic sectional view thereof taken along a line 4B-4B in FIG. 4(A), and FIG. 4(C) is a schematic sectional view thereof taken along a line 4C-4C in FIG. 4(A);

FIGS. 5(A) to 5(C) are schematic views No. 4 showing the method of producing the semiconductor device according to the embodiment of the present invention, wherein FIG. 5(A) is a schematic plan view thereof, FIG. 5(B) is a schematic sectional view thereof taken along a line 3B-3B in FIG. 5(A), and FIG. 5(C) is a schematic sectional view thereof taken along a line 5C-5C in FIG. 5(A);

FIGS. 6(A) to 6(C) are schematic views No. 5 showing the method of producing the semiconductor device according to the embodiment of the present invention, wherein FIG. 6(A) is a schematic plan view thereof, FIG. 6(B) is a schematic sectional view thereof taken along a line 3B-3B in FIG. 6(A), and FIG. 6(C) is a schematic sectional view thereof taken along a line 6C-6C in FIG. 6(A);

FIGS. 7(A) to 7(C) are schematic views No. 6 showing the method of producing the semiconductor device according to the embodiment of the present invention, wherein FIG. 7(A) is a schematic plan view thereof, FIG. 7(B) is a schematic sectional view thereof taken along a line 3B-3B in FIG. 7(A), and FIG. 7(C) is a schematic sectional view thereof taken along a line 7C-7C in FIG. 7(A); and

FIGS. 8(A) to 8(C) are schematic views No. 7 showing the method of producing the semiconductor device according to the embodiment of the present invention, wherein FIG. 8(A) is a schematic plan view thereof, FIG. 8(B) is a schematic sectional view thereof taken along a line 8B-8B in FIG. 8(A), and FIG. 8(C) is a schematic sectional view thereof taken along a line 8C-8C in FIG. 8(A).

### DETAILED DESCRIPTION OF PREFERRED EMBODIMENTS

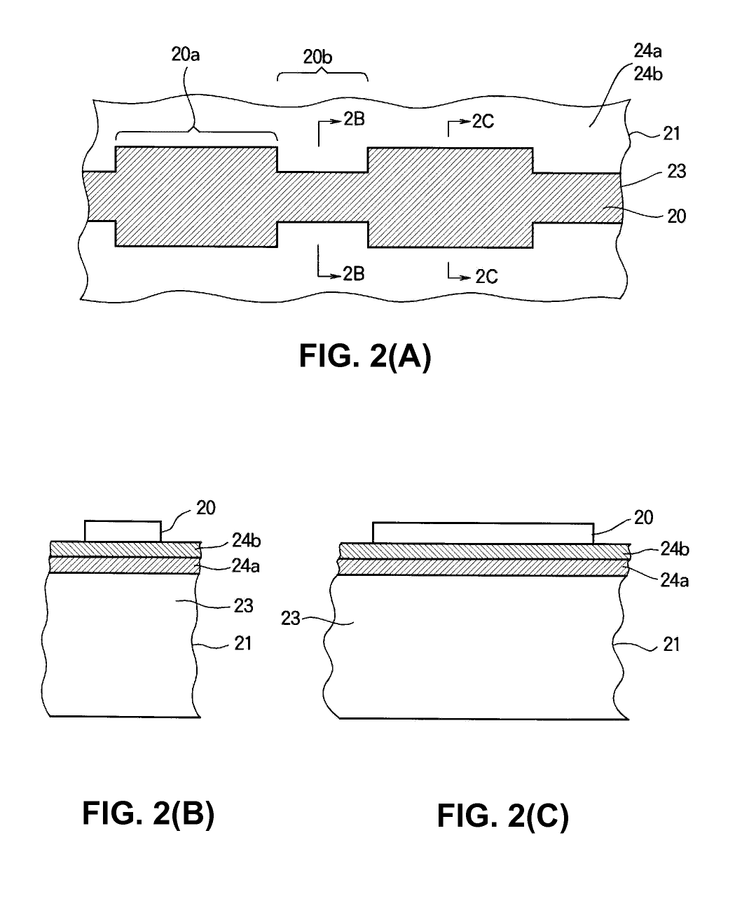

Hereunder, preferred embodiments of the present invention will be explained with reference to the accompanying drawings FIGS. 2(A) to 2(C) to FIGS. 8(A) to 8(C).

FIGS. 2(A) to 2(C) are schematic views No. 1 showing a method of producing a semiconductor device according to an embodiment of the present invention. More specifically, FIG. 2(A) is a schematic plan view thereof, FIG. 2(B) is a schematic sectional view thereof taken along a line 2B-2B in FIG. 2(A), and FIG. 2(C) is a schematic sectional view thereof taken along a line 2C-2C in FIG. 2(A).

In the method of producing the semiconductor device according to an embodiment of the present invention, first, as shown in FIGS. 2(A) to 2(C), a P-type silicon (Si) substrate 21 is prepared as a semiconductor substrate of a first conductive type. In the next step, a silicon oxide film 24a and a silicon nitride film 24b are formed on an entire area of a main surface (an upper surface in FIGS. 2(B) and 2(C)) of the P-type silicon substrate 21.

In the next step, a mask layer 20 formed of a resist is formed on the silicon nitride film 24b through a photo-lithography technology. It is noted that the mask layer 20 has a wide width portion 20a and a narrow width portion 20b. In the next step, while the mask layer 20 covers and protects the silicon nitride film 24b, a trench 24 is formed in the P-type silicon substrate 21, the silicon oxide film 24a, and the silicon nitride film 24b through an etching (for example, dry etching). At this moment, an active region (AC) 23 formed of the P-type silicon substrate 21 is formed and remains.

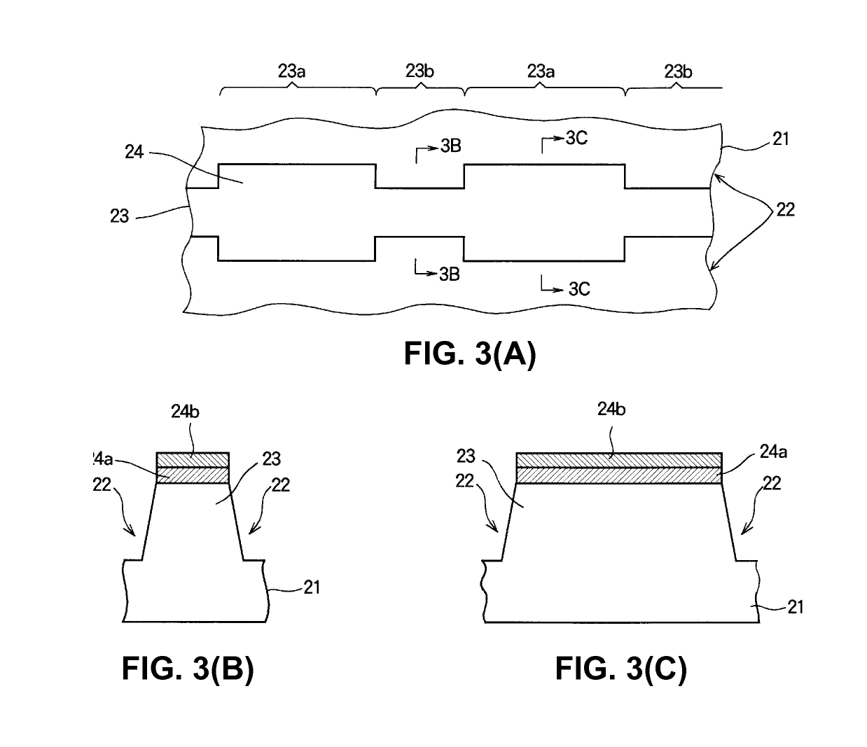

In the next step, the mask layer 20 is removed. Accordingly, as shown in FIGS. 3(A) to 3(C), a trench 22 is formed, and the active region 23, the silicon oxide film 24a on the active region 23, and the silicon nitride film 24b on the silicon oxide film 24a remain. As shown in FIG. 3(A), the active region 23 has a wide width portion 23a and a narrow width portion 23b. In the embodiment, a field effect transistor (FET) of a depletion type is formed in the wide width portion 23a in a later step, and a field effect transistor (FET) of an enhancement type is formed in the narrow width portion 23b in a later step.

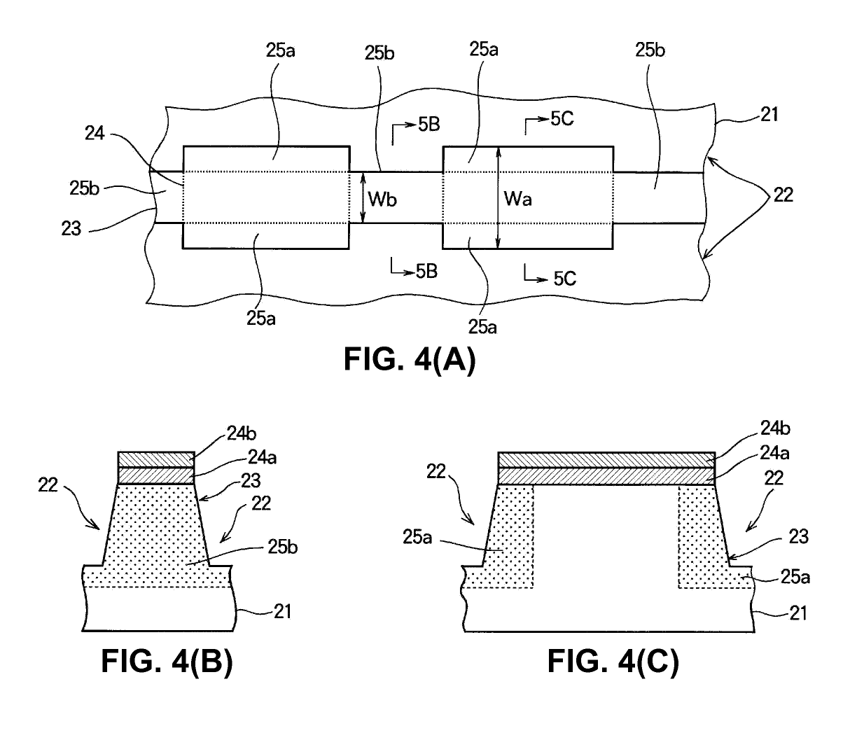

In the next step, as shown in FIGS. 4(A) to 4(C), before the trench 22 is filled with an insulation layer, a P-type impurity D1 (for example, boron) as a first conductive type impurity is ion implanted (a rotational oblique ion implantation process) in an arrow direction D1, so that a channel stopper region is formed.

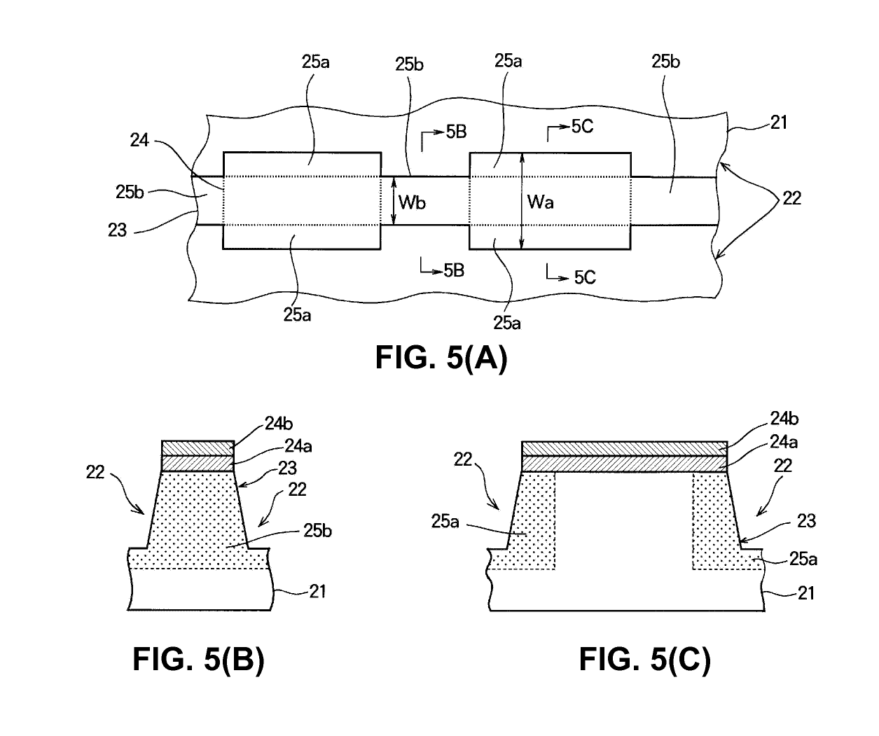

In the embodiment, the P-type impurity D1 is implanted at an implantation energy of, for example, 30 keV, and a dose amount per unit area is, for example, about 5×10¹² cm⁻². Further, the P-type impurity D1 is implanted at an implantation angle α of, for example, 30 degrees relative to a normal line of the main surface of the P-type silicon substrate 21 in a direction rotating around. Accordingly, a channel stopper region 25a is formed in the area, in which the FET of the depletion type is formed, and a P-type channel diffusion region 25b is formed in the area, in which the FET of the enhancement type is formed (refer to FIGS. 5(B) and 5(C)).

As described above, in the embodiment, the P-type impurity D1 is implanted at the specific implantation energy, the specific dose amount, and the specific implantation angle α. The present invention is not limited to the specific implantation energy, the specific dose amount, and the specific implantation angle α.

In the rotational oblique ion implantation process, the P-type silicon substrate 21 is rotated, and the P-type impurity D1 is implanted at an inclined angle from every direction around a center axis of the P-type silicon substrate 21. The implantation angle α is preferably in a range between 30 degrees and 45 degrees. Alternatively, the P-type silicon substrate 21 may be stationary, and an ion implantation device may rotate around the P-type silicon substrate 21.

In the rotational oblique ion implantation process, in the narrow width portion 23b with an active region width Wb, the P-type impurity D1 is implanted in an entire region below the silicon oxide film 24a. Accordingly, the P-type channel diffusion region 25b with a high concentration is formed as shown in FIG. 5(B). On the other hand, in the wide width portion 23a with an active region width Wa, the P-type impurity D1 is implanted only in an edge region in a width direction below the silicon oxide film 24a. Accordingly, as shown in FIG. 5(C), a center portion below the silicon oxide film 24a remains as a P-type diffusion layer with a low concentration.

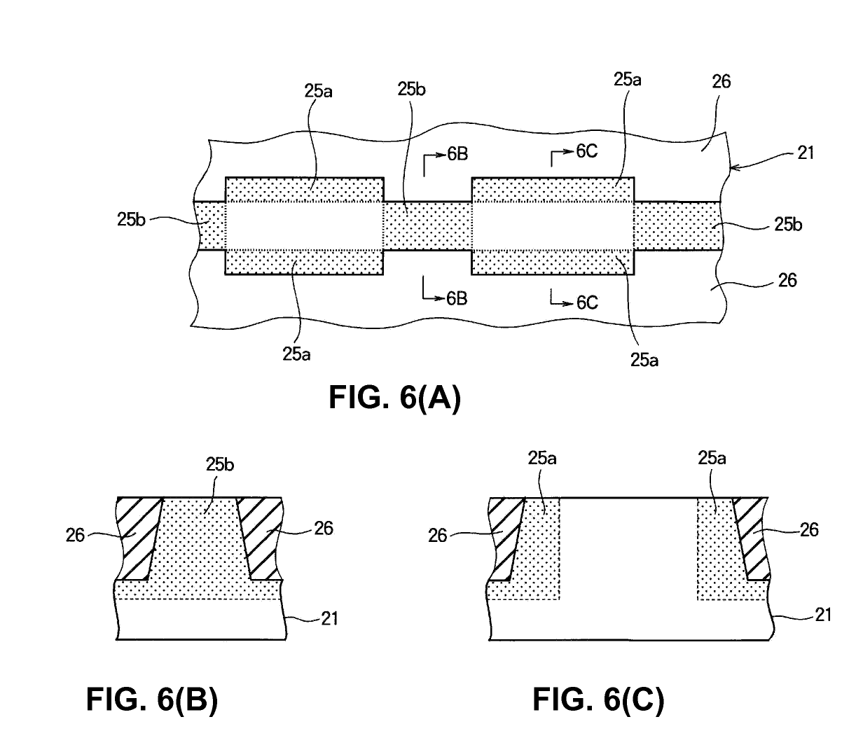

In the next step, as shown in FIGS. 6(B) and 6(C), after the trench 22 is filled with the insulation layer, a surface is polished and flattened with, for example, a CMP (Chemical Mechanical Polishing) method, thereby forming a trench element separation insulation layer 26.

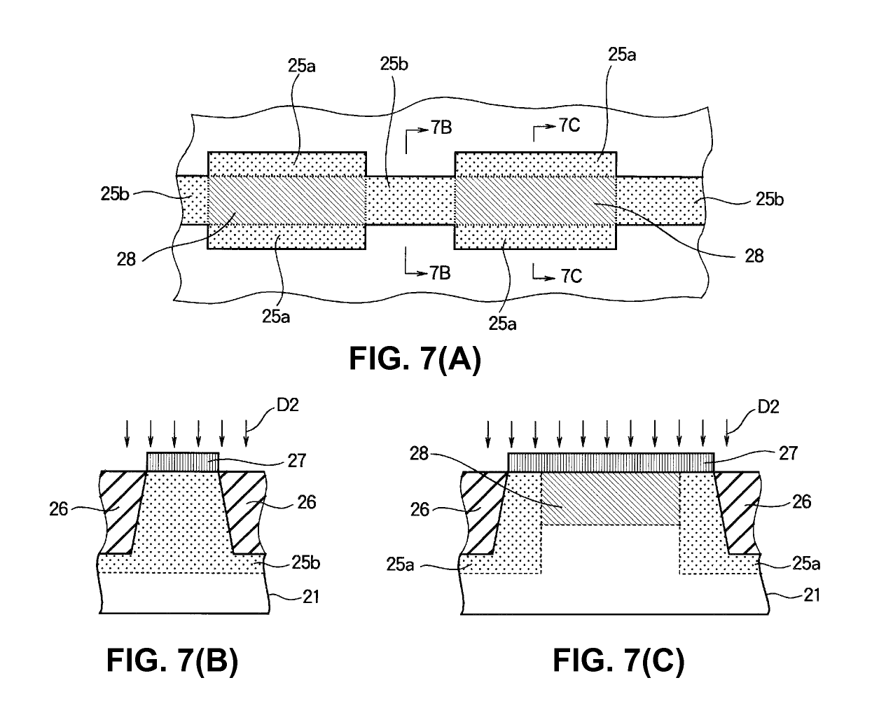

In the next step, as shown in FIGS. 7(A) to 7(C), a gate insulation film 27 with a specific shape (not shown in FIG. 7(A)) is formed on a surface area of a surrounding region of the trench element separation insulation layer 26. In the embodiment, the gate insulation film 27 is formed of, for example, a gate oxide film, and has a thickness of, for example, 500 Å. The thickness of the gate insulation film 27 is not limited to 500 Å.

In the next step, an N-type impurity D2 (for example, phosphorus) is ion implanted to form an N-type impurity low concentration diffusion layer 28 (an N-type channel diffusion region) as a second conductive type impurity low concentration diffusion layer of the MOS-FET. In the embodiment, the N-type impurity D2 is implanted at an implantation energy of, for example, 200 keV, and a dose amount per unit area is, for example, about 2×10¹² cm⁻². Further, the N-type impurity D2 is implanted at an implantation angle of, for example, 0 degree (perpendicular to the main surface of the P-type silicon substrate 21).

As described above, in the embodiment, the N-type impurity D2 is implanted at the specific implantation energy, the specific dose amount, and the specific implantation angle. The present invention is not limited to the specific implantation energy, the specific dose amount, and the specific implantation angle. It is noted that the N-type impurity D2 is implanted at the dose amount per unit area smaller than the dose amount per unit area of the P-type impurity D1 shown in FIGS. 4(A) to 4(C). Accordingly, it is possible to remain a high concentration P-type channel diffusion region as the P-type channel diffusion region 25b of the enhanced type without converting to the N-type.

In the embodiment, the gate insulation film 27 is formed before the N-type impurity D2 is implanted. Alternatively, the gate insulation film 27 may be formed after the N-type impurity D2 is implanted. When the gate insulation film 27 is formed before the N-type impurity D2 is implanted, it is possible to prevent the N-type impurity low concentration diffusion layer 28 from being forming in an irregular shape during the forming process of the gate insulation film 27. Accordingly, it is preferred that the gate insulation film 27 is formed before the N-type impurity D2 is implanted.

In the ion implantation process described above, in the narrow width portion 23b with the active region width Wb, the P-type impurity diffusion layer of the P-type channel diffusion region 25b remains as the P-type impurity channel diffusion region as shown in FIG. 7(B). On the other hand, in the wide width portion 23a with the active region width Wa, the P-type impurity of the channel stopper region 25a remains in an edge region in a width direction below the silicon oxide film 24a. Accordingly, as shown in FIG. 7(C), a center portion below the silicon oxide film 24a remains as an N-type diffusion region 28 with a low concentration.

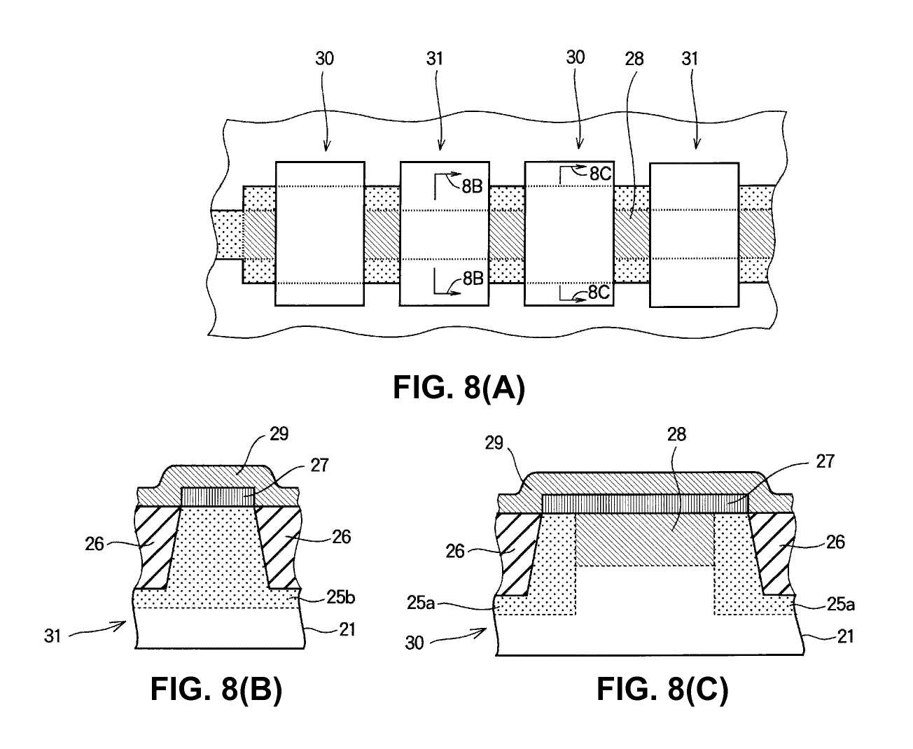

In the next step, as shown in FIGS. 8(A) to 8(C), a gate electrode 29 is formed on the gate insulation film 27. The gate electrode 29 is formed of poly-silicon and the like, and has a thickness of about 2,000 Å. The thickness of the gate electrode 29 is not limited thereto. As shown in FIG. 8(C), an FET 30 of the depletion type is formed in a region including the channel stopper region 25a and the N-type impurity low concentration diffusion layer 28. As shown in FIG. 8(B), an FET 31 of the enhancement type is formed in a region including the P-type channel diffusion region 25b.

In the embodiment, through the steps described above, it is possible to form both the FET 30 of the depletion type and the FET 31 of the enhancement type on the same semiconductor substrate as shown in FIGS. 8(A) to 8(C).

As described above, in the embodiment, the P-type impurity is implanted at the inclined angle in the rotating direction in the rotational oblique ion implantation process (one single process). Accordingly, in the semiconductor device and the method of producing the semiconductor device according to the embodiment of the present invention, it is possible to concurrently form the P-type channel diffusion region 25b of the FET 31 of the enhancement type and the channel stopper region 25a of the FET 30 of the depletion type. As a result, it is possible to eliminate a separate ion plantation process for forming the channel stopper region 25a of the FET 30 of the depletion type, or a corresponding step of forming a mask.

Further, in the semiconductor device and the method of producing the semiconductor device according to the embodiment of the present invention, the P-type impurity is implanted into the entire area of the P-type silicon substrate 21 (that is, an entire area of an ROM transistor forming area when an ROM transistor is produced) at the inclined angle in the rotating direction. Accordingly, it is not necessary to form a mask for implanting the P-type impurity at the inclined angle in the rotating direction. Further, it is not necessary to provide a matching margin of the mask in the step of forming the mask, thereby reducing a size of the semiconductor device.

Further, in the semiconductor device and the method of producing the semiconductor device according to the embodiment of the present invention, it is not necessary to form a mask when the N-type impurity is implanted. Accordingly, it is possible to eliminate the step of forming the mask and reduce a size of the semiconductor device.

In the embodiment, described above, the first conductive type is the P-type, and the second conductive type is the N-type. Alternatively, the first conductive type may be the P-type, and the second conductive type may be the N-type. In this case, it is possible to produce a semiconductor device with an opposite conductive type.

The disclosure of Japanese Patent Application No. 2010-035901, filed on Feb. 22, 2010, is incorporated in the application by reference.

While the invention has been explained with reference to the specific embodiments of the invention, the explanation is illustrative and the invention is limited only by the appended claims.

What is claimed is:

1. A method of producing a semiconductor device comprising:
forming a trench in a main surface of a semiconductor substrate of a first conductive type to form an active region having a first portion with a first width and a second region with a second width greater than the first width in the semiconductor substrate;
implanting a first impurity of the first conductive type in the semiconductor substrate through a mask formed on the first portion and the second portion at a specific implantation angle relative to a normal line of the main surface in a specific implantation direction to form a first channel diffusion region of the first conductive type in the first portion and a channel stopper region of the first conductive type in the second portion;
filling the trench with an insulation layer;
implanting a second impurity of a second conductive type different from the first conductive type in the semiconductor substrate to form a second channel diffusion region of the second conductive type between the channel stopper regions in the second portion; and
forming a gate electrode on the first portion and the second portion.

2. The method of producing the semiconductor device according to claim 1, further comprising the step of forming a gate insulation film on the first portion and the second portion before the step of forming the gate electrode, said gate electrode being formed on the gate insulation film.

3. The method of producing the semiconductor device according to claim 2, wherein the step of forming the gate insulation film on the first portion and the second portion is performed before the step of implanting the second impurity of the second conductive type different from the first conductive type in the semiconductor substrate is performed.

4. The method of producing the semiconductor device according to claim 2, wherein the step of forming the gate insulation film on the first portion and the second portion is performed after the step of implanting the second impurity of the second conductive type different from the first conductive type in the semiconductor substrate is performed.

5. The method of producing the semiconductor device according to claim 1, wherein, in the step of implanting the second impurity of the second conductive type different from the first conductive type in the semiconductor substrate, the second impurity is implanted at a does amount per unit area smaller than that of the first impurity in the step of implanting the first impurity of the first conductive type in the semiconductor substrate.

6. The method of producing the semiconductor device according to claim 1, further comprising the step of flattening the main surface of the semiconductor substrate after the step of filling the trench with the insulation layer is performed.

7. The method of producing the semiconductor device according to claim 1, wherein, in the step of implanting the first impurity of the first conductive type in the semiconductor substrate, the first impurity is implanted at the specific implantation angle inclined relative to the normal line of the main surface while the semiconductor substrate is rotated.

8. The method of producing the semiconductor device according to claim 1, wherein, in the step of implanting the first impurity of the first conductive type in the semiconductor substrate, the first impurity is implanted at the specific implantation angle between 30 degrees and 45 degrees relative to the normal line of the main surface.

9. The method of producing the semiconductor device according to claim 1, wherein, in the step of implanting the first impurity of the first conductive type in the semiconductor substrate, the first impurity is implanted in the specific implantation direction rotating relative to the normal line.

10. The method of producing the semiconductor device according to claim 1, further comprising the step of forming the mask on the main surface of the semiconductor substrate, said trench being formed in the main surface using the mask, said first impurity being implanted in the semiconductor substrate using the mask.

11. The method of producing the semiconductor device according to claim 1, wherein, in the step of implanting the second impurity in the semiconductor substrate, the second impurity is implanted in an entire region of the first portion and an edge region of the second portion so that the first impurity remains in a center region of the second portion.

12. The method of producing the semiconductor device according to claim 1, wherein, in the step of forming the trench in the main surface of the semiconductor substrate, the first portion is formed to continuously connect to the second portion.

13. A method of producing a semiconductor device comprising:
forming a trench in a main surface of a semiconductor substrate of a first conductive type so that an active region having a first portion with a first width and a second region with a second width greater than the first width is formed in the semiconductor substrate;
implanting a first impurity of the first conductive type in the semiconductor substrate at an implantation angle between 30 degrees and 45 degrees relative to a normal line of the main surface in an implantation direction rotating relative to the normal line so that a first channel diffusion region of the first conductive type is formed in the first portion and a channel stopper region of the first conductive type is formed in the second portion;
filling the trench with an insulation layer;
implanting a second impurity of a second conductive type different from the first conductive type in the semiconductor substrate so that a second channel diffusion region of the second conductive type is formed between the channel stopper regions in the second portion;
forming a gate insulation film on the first portion and the second portion; and
forming a gate electrode on the gate insulation film.
